(19) United States
(12) Patent Application Publication
(10) Pub. No.: US 2015/0280087 A1
(43) Pub. Date: Oct. 1, 2015

(54) LIGHT-EMITTING DIODE HAVING A SILICON SUBMOUNT AND LIGHT-EMITTING DIODE LAMP

(71) Applicant: Leadray Energy Co Ltd., Toufen Township (TW)

(72) Inventor: Kuei-Fang CHEN, Toufen Township (TW)

(21) Appl. No.: 14/542,609

(22) Filed: Nov. 16, 2014

(30) Foreign Application Priority Data
Mar. 26, 2014 (TW) 103205180

(51) Int. Cl. H01L 33/62; H01L 33/48; F21V 29/70; H01L 33/64

(52) U.S. Cl. CPC H01L 33/62; H01L 33/642; H01L 33/486; F21V 29/70; F21Y 2101/02

(57) ABSTRACT

A light-emitting diode having a silicon submount includes a silicon submount and a light-emitting diode (LED) chip. The silicon submount includes a power management integrated circuit formed in an inside of the silicon submount, a P-electrode formed on a bottom side thereof, an N-electrode formed on the bottom side thereof, and a heat dissipation ground portion formed on the bottom side thereof. The power management integrated circuit is electrically coupled to the P-electrode and the N-electrode. The LED chip is eutecticly bonded to a top side of the silicon submount, and the LED chip is electrically coupled to the P-electrode and the N-electrode. A heat-dissipation channel is defined from the LED chip to the heat dissipation ground portion via the inside of the silicon submount. The power management integrated circuit replaces a conventional power supply controller, thereby providing a more optimized LED.

### CROSS-REFERENCE TO RELATED APPLICATIONS

This application claims the benefit of priority of Taiwan Patent Application No. 103205180 filed Mar. 26, 2014, the contents of which are incorporated herein by reference in their entirety.

### TECHNICAL FIELD OF THE INVENTION

The present invention relates to a lighting fixture, and in particular to a light-emitting diode having a silicon submount and a light-emitting diode lamp.

### BACKGROUND OF THE INVENTION

Whether in a commercial office, school, home, car, street, etc., there is always a demand for lighting fixtures with a high brightness. Common halogen lamps have ceased to be a favorite with the market due to the shortcomings that it will cause deterioration of the irradiated objects, high electricity cost, and so on. Gradually, a light-emitting diode (LED) lamp with high brightness but low electricity cost has eliminated many of the shortcomings of the halogen lamp and has become the mainstream of current lighting fixtures.

However, the conventional LED lamp consists of light-emitting diodes, a circuit board, a power controller, and a heatsink. In addition to the waste heat that the LED produces, the power controller also produces a lot of waste heat. Without a fast and efficient heat-dissipation design, the light-emitting diodes will be unable to be densely arranged, and the power controller also will also be required to be kept a certain distance apart from the light-emitting diodes. These respectively cause the drawbacks that the brightness cannot be enhanced and the size of the LED lamp cannot be reduced. Moreover, since the size of the conventional power controller itself is enormous and much larger than the light-emitting diodes and the circuit board, the size of the LED lamp cannot be reduced. Therefore, the LED lamp cannot be flexible and convenient to use; for example, it will occupy a certain thickness and depth for installation when it is utilized as a cabinet light.

According to the disclosure of the applicant's previous Taiwan Invention Patent No. 1418736, a LED lamp with an excellent heat-dissipation design has been provided. Under the concept of the heat-dissipation design disclosed in that patent, how to further improve the competitiveness of the LED lamp is a current research focus in the related industries.

### SUMMARY OF THE INVENTION

Therefore, an objective of the present invention is to provide a more optimized LED having a silicon submount.

Thus, another objective of the present invention is to provide a more optimized LED lamp with a substantial reduction in size.

Accordingly, a light-emitting diode having a silicon submount according to the present invention includes a silicon submount and at least one LED chip. The silicon submount includes a power management integrated circuit formed in an inside of the silicon submount, a P-electrode formed on a bottom side thereof, an N-electrode formed on the bottom side thereof, and a heat dissipation ground portion formed on the bottom side thereof. The power management integrated circuit is electrically coupled to the P-electrode and the N-electrode. The light-emitting diode chip is eutecticly bonded to a top side of the silicon submount. The at least one LED chip is electrically coupled to the P-electrode and the N-electrode, in which a heat-dissipation channel is defined from the LED chip to the heat dissipation ground portion via the inside of the silicon submount.

The LED lamp of the present invention includes a heatsink, a circuit board, at least one light-emitting diode, and a pair of wires. The heatsink includes a flat reference surface and a plurality of heatsink platforms protruding from the reference surface. The circuit board includes a heatsink bottom surface correspondingly contacting the reference surface of the heatsink and a plurality of grooves defined therein corresponding to the heatsink platforms. The heatsink platforms are positioned in the grooves. The light-emitting diode is disposed above the grooves of the circuit board and located on top surfaces of the heatsink platforms of the heatsink. The light-emitting diode includes a silicon submount and at least one light-emitting diode chip. The silicon submount includes a power management integrated circuit formed in an inside of the silicon submount, a P-electrode formed on a bottom side thereof, an N-electrode formed on the bottom side thereof, and a heat dissipation ground portion formed on the bottom side thereof. The power management integrated circuit is electrically coupled to the P-electrode and the N-electrode. The LED chip is eutecticly bonded to a top side of the silicon submount, and the LED chip is electrically coupled to the P-electrode and the N-electrode. A heat-dissipation channel is defined from the LED chip to the heat dissipation ground portion via the inside of the silicon submount. The pair of wires is utilized to make the circuit board be coupled to an external power supply.

The advantages of the present invention are that the power management integrated circuit can be directly designed to be disposed in the inside of the silicon submount to replace the conventional power controller since the LED lamp has excellent heat-dissipation design. A more optimized light-emitting diode is provided, and the size of the LED lamp can therefore be significantly reduced, thereby achieving the objectives of the present invention.

### BRIEF DESCRIPTION OF THE DRAWINGS

The present invention will now be described in detail with reference to a few preferred embodiments thereof as illustrated in the accompanying drawings, in which:

FIG. 1 is an exploded perspective view illustrating a first preferred embodiment of the light-emitting diode having a silicon submount and LED lamp of the present invention;

FIG. 2 is a perspective view illustrating a heatsink, a circuit board, a plurality of light-emitting diodes, and a pair of wires of the first preferred embodiment;

FIG. 3 is a schematic sectional view illustrating a silicon submount and a plurality of light-emitting diodes of the first preferred embodiment;

FIG. 4 is a schematic top view illustrating the silicon submount and the plurality of light-emitting diodes of the first preferred embodiment;

FIG. 5 is a schematic bottom view illustrating a P-electrode, an N-electrode and a heat dissipation ground portion of the first preferred embodiment; and

FIG. 6 is an exploded perspective view illustrating a second preferred embodiment of the light-emitting diode having a silicon submount and the LED lamp of the present invention.

### DETAILED DESCRIPTION OF THE INVENTION

Before describing the present invention in detail, it must be noted that the same reference numerals in the following description refer to the same parts or like parts throughout the various figures.

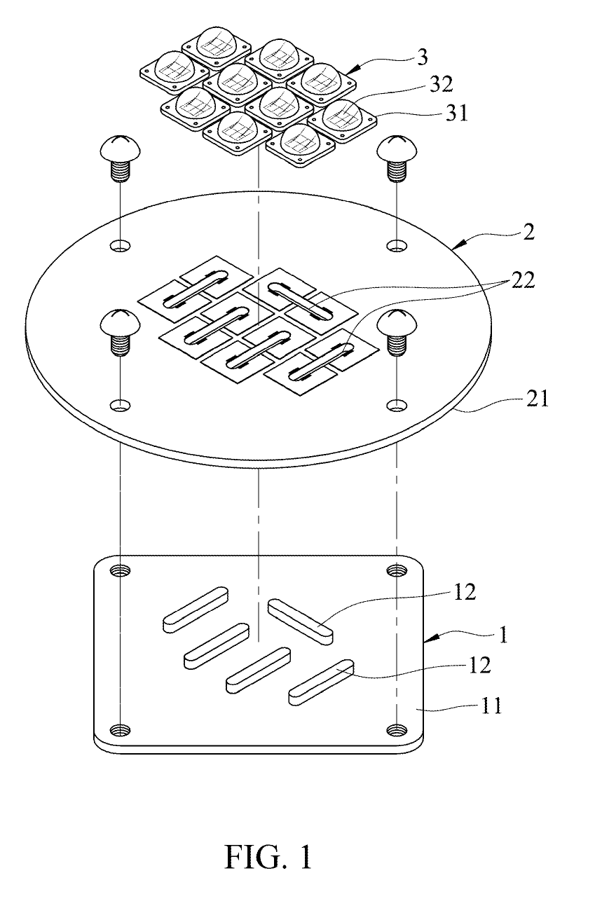

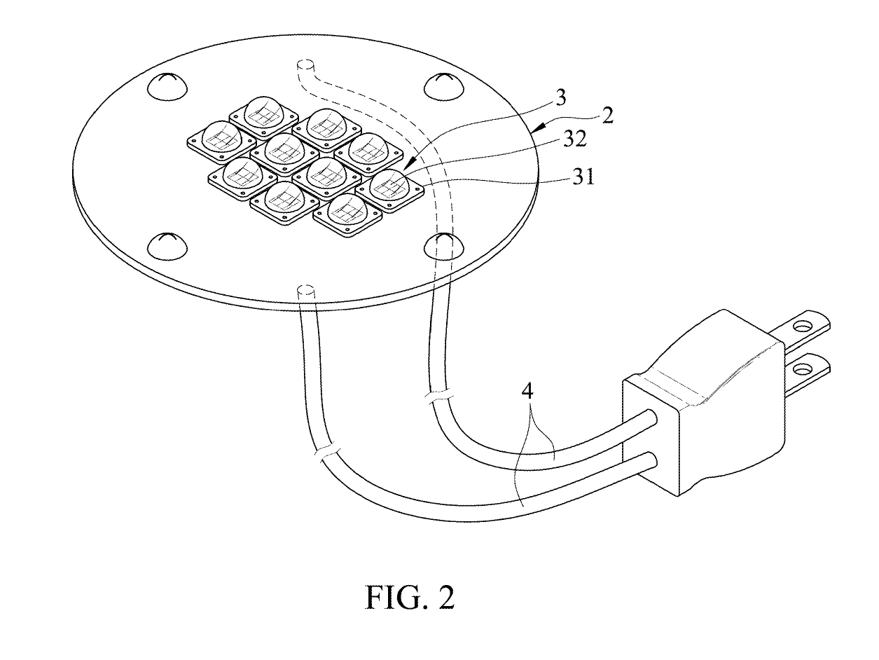

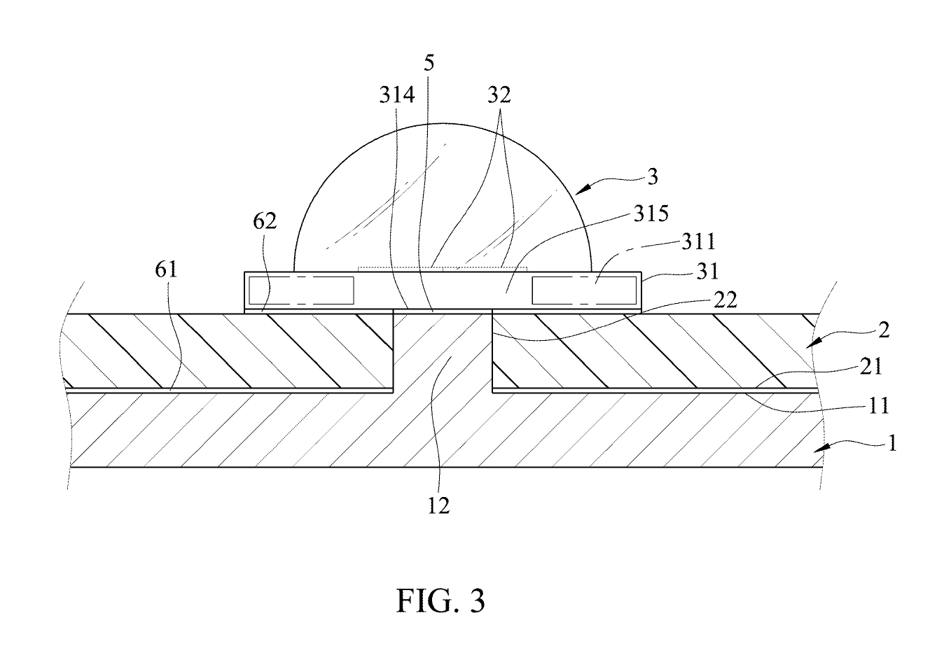

Referring to FIG. 1, FIG. 2, and FIG. 3, in a first preferred embodiment of a light-emitting diode having a silicon submount and the LED lamp of the present invention, the LED lamp includes a heatsink 1, a circuit board 2, a plurality of light-emitting diodes 3, a pair of wires 4, and an intermetallic layer 5.

The heatsink 1 includes a flat reference surface 11 and a plurality of heatsink platforms 12 that protrude from the reference surface 11. The heatsink 1 can be made of copper with a heat transfer coefficient of 380 W/m ·K, or aluminum with a heat transfer coefficient of 273 W/m ·K. Both can quickly exhaust heat.

The circuit board 2 includes a heatsink bottom surface 21 correspondingly contacting the reference surface 11 of the heatsink 1 and a plurality of grooves 22 defined therein corresponding to the heatsink platforms 12. The heatsink platforms 12 are positioned in the grooves 22 of the circuit board 2 correspondingly.

The light-emitting diodes 3 are disposed above the grooves 22 of the circuit board 2 and located on top surfaces of the heatsink platforms 12 of the heatsink 1. The light-emitting diodes 3 respectively include a silicon submount 31 and a plurality of LED chips 32.

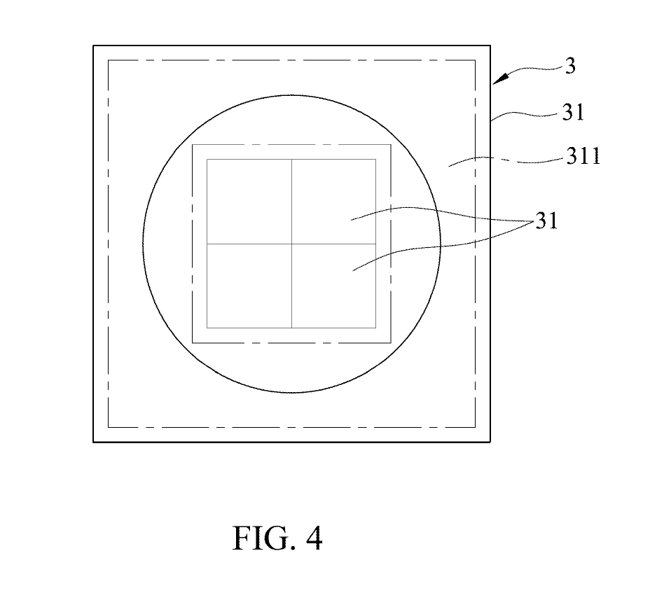

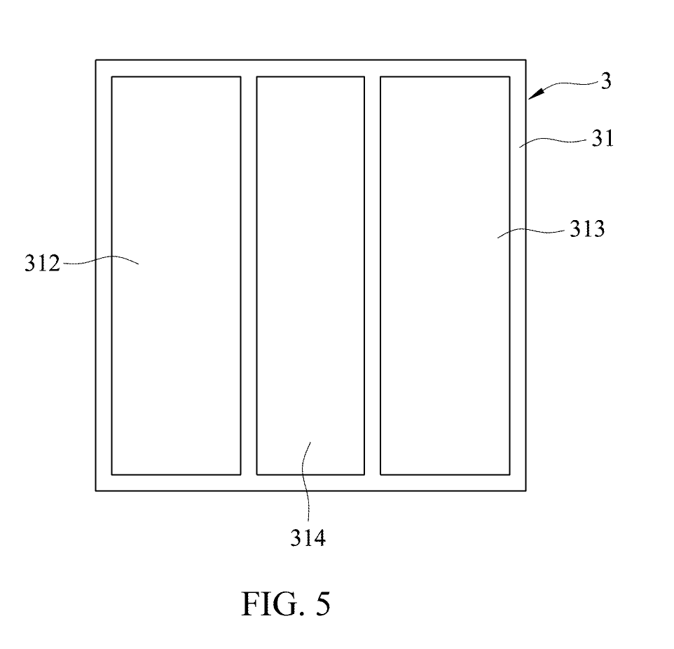

Also referring to FIG. 4 and FIG. 5, the material of the silicon submount 31 is silicon, which has a heat transfer coefficient of 170 W/m ·K. The silicon submount 31 includes a power management integrated circuit 311 formed in an inside thereof, a P-electrode 312 formed on a bottom side thereof, an N-electrode 313 formed on the bottom side thereof, and a heat dissipation ground portion 314 formed on the bottom side thereof. The power management integrated circuit 311 is electrically coupled to the P-electrode 312 and the N-electrode 313. A heat-dissipation channel 315 is defined from the LED chips 32 to the heat dissipation ground portion 314 via the inside of the silicon submount 31. The heat-dissipation channel 315 is vertically downward.

The power management integrated circuit 311 is formed in the inside of the silicon submount 31 by using a technique of semiconductor epitaxial growth for forming the integrated circuits which include capacitors, inductors, resistors, etc.

One of functions of the heat dissipation ground portion 314 is grounding. According to lighting fixture standards set by the International Electrotechnical Commission, a lower limit of withstand voltage for the LED lamp having the grounding function is 500VAC. In the first preferred embodiment, the withstand voltage of the light-emitting diodes 3 is as high as 700 VAC.

Another function of the heat dissipation ground portion 314 is heat dissipation, being capable of transferring the heat of the power management integrated circuit 311 and the LED chip 32 outward. Since the heat dissipation ground portion 314 is coupled to the heatsink platform 12 of the heatsink 1, the heatsink 1 can effectively take away the waste heat of the silicon submount 31.

That is to say, in the first preferred embodiment, the heat-dissipation channel 315 and the grounding function share the heat dissipation ground portion 314. More specifically, the power management integrated circuit 311 is disposed around the heat-dissipation channel 315. The consideration for this design is that the LED chips 32 need an excellent cooling effect in comparison with the power management integrated circuit 311. Thus, the space of the heat-dissipation channel 315 purely serves for heat dissipation. The power management integrated circuit 311 does not be disposed or formed in the above-mentioned space of the heat-dissipation channel 315, whereby the heat from the LED chips 32 can be transferred outward more quickly.

The power management integrated circuit 311 of the silicon submount 31 can be designed according to different external power supplies, whereby the external power supplies can be applied to the light-emitting diodes 3 of 20W, the light-emitting diode 3 of 30W, etc. so that the voltage and current can be matched with each other, and it controls the voltage value assigned to a single light-emitting diode 3 to avoid burning out the light-emitting diode 3. Moreover, the power management integrated circuit 311 can control the brightness of the light-emitting diodes 3.

Then since the power management integrated circuit 311 in the inside of the silicon submount 31 has replaced the power controller within the conventional LED lamp, the heatsink made for the power controller of the conventional LED lamp can be omitted. In the past, the power management integrated circuit 311 and the LED chips 32 failed to be put together due to the heat-dissipation design, but the technical bottleneck in the past can be broken through the applicant's previous Taiwan Invention Patent No. 1418736.

In the past, the substrate (submount) of the light-emitting diodes 3 could be made of aluminum nitride, aluminum oxide, or other materials. For instance, the substrate of Philips is made by means of aluminum nitride surrounded by alumina. Although aluminum nitride compared to silicon has a higher heat transfer coefficient, it basically only has the effects of heat transfer and insulation. Therefore, silicon still is the best material for growing the power management integrated circuit 311 by semiconductor epitaxy.

It is worth mentioning that, in the first preferred embodiment, a thermal management integrated circuit, a color-control integrated circuit, and so on can further be designed to be within the silicon submount 31. Both the thermal management integrated circuit and the color-control integrated circuit (not shown) can be formed in the inside of the silicon submount 31 by the same semiconductor epitaxy technique that grows the power management integrated circuit 311.

The LED chips 32 are eutecticly bonded to a top side of the silicon submount 31, and the LED chips 32 are electrically coupled to the P-electrode 312 and the N-electrode 313, respectively. In the first preferred embodiment, the LED chips 32 are made of gallium nitride. Since there is a lattice mismatch between gallium nitride and silicon, the LED chips 32 cannot directly grow on the silicon submount 31 by the semiconductor epitaxy technique. Thus, this installation problem is solved by using the eutectic bonding manner. Furthermore, a yield rate thereof by using the eutectic bonding is high, and cooling efficiency thereof is also higher than that by using silver paste for the bonding.

The pair of wires 4 is utilized to couple the circuit board 2 to an external power supply, such as DC/AC. The DC may come from solar energy, a battery, and so on. Specifications for the DC may be 12V, 24V, etc.; specifications for the AC may be 110V, 210V, etc.

The intermetallic layer 5 is positioned between the heat dissipation ground portion 314 of the silicon submount 31 of the light-emitting diodes 3 and the top surface of the heatsink platform 12 of the heatsink 1.

The heatsink 1 and the circuit board 2 are welded by using a high-melting-point tin solder 61; the light-emitting diodes 3 and the heatsink 1 as well as the circuit board 2 are respectively welded by using a low-melting-point tin solder 62. The melting point of the high-melting-point tin solder 61 is 260° C.; the melting point of the low-melting-point tin solder 62 is 150° C.

An order of the welding is: the circuit board 2 and the heatsink 1 are welded firstly by using the high-melting-point tin solder 61, and then the light-emitting diodes 3 and the heatsink 1 as well as the circuit board 2 are welded by using the low-melting-point tin solder 62. Then the melting point of the low-melting-point tin solder 62 is lower than that of the high-melting-point tin solder 61, so the tin solder of the high-melting-point tin solder 61 between the circuit board 2 and the heatsink 1 doesn't melt while subsequently welding the light-emitting diodes 3 and the heatsink 1 as well as the circuit board 2.

The top surface of the heatsink platform 12 of the heatsink 1 plus the intermetallic layer 5 is higher than the circuit board 2. A thickness of the intermetallic layer 5 is less than 0.03 mm, thereby avoiding the phenomena of poor contact, such as empty solder, resulting from the light-emitting diodes 3 being too far from the circuit board 2. Both the heat dissipation ground portion 314 of the silicon submount 31 and the top surface of the heatsink platform 12 of the heatsink 1 have a gold-tin alloy layer formed thereon, such that the heatsink 1 retains the heat transfer coefficient of anaerobic copper and anaerobic aluminum before and after the welding. The gold-tin alloy layer forms the intermetallic layer 5 after the welding. An air gap between the heat dissipation ground portion 314 of the silicon submount 31 and the top surface of the heatsink platform 12 of the heatsink 1 can be filled by the low-melting-point tin solder 62. The connection between the light-emitting diodes 3 and the heatsink 1 is closer, and the low-melting-point tin solder 62 left by the welding is very thin. By using the low-melting-point tin solder 62 for filling the air gap, the reduction of the heat dissipation due to the air is avoided, and it can effectively improve the contact area between the light-emitting diodes 3 and the heatsink 1, thus enhancing the heat-dissipation effect. In addition, before the welding, the gold in metal elements of the gold-tin alloy layer can be utilized to avoid oxidation of the heatsink 1 by its inertness. While welding, the tin in the metallic elements of the gold-tin alloy layer can be utilized to lower the melting point, preventing the tin solder of the high-melting-point tin solder 61 melting.

More specifically, since the top surface of the heatsink platform 12 of the heatsink 1 is not lower than the circuit board 2, a predetermined pressure is applied while welding, such that the thickness of the intermetallic layer 5 between the light-emitting diodes 3 and the heatsink 1 becomes thin and uniform.

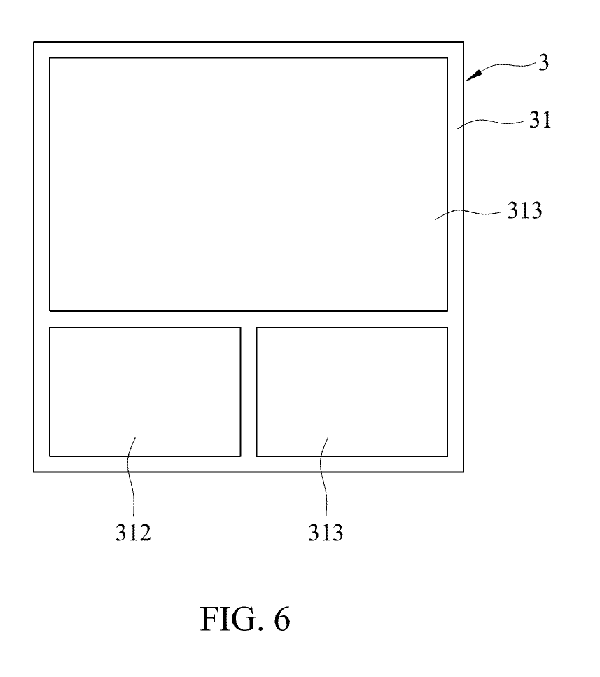

Referring to FIG. 6, a second preferred embodiment of the light-emitting diode having a silicon submount and the LED lamp of the present invention is roughly the same to the first preferred embodiment. The difference therebetween is that the position arrangement of the P-electrode 312, the N-electrode 313, and the heat dissipation ground portion 314 is different from that of the first preferred embodiment. In the second preferred embodiment, the P-electrode 312 and the N-electrode 313 are located side by side on one side, and the heat dissipation ground portion 314 is located on the other side.

In summary, the advantages of the present invention are that the power management integrated circuit 311 can be designed to be directly disposed in the inside of the silicon submount 31 to replace the conventional power controller because the LED lamp of the present invention has an excellent heat-dissipation design. A more optimized light-emitting diode is provided. The present invention, which can dramatically improve product performance, has a luminous flux of 1916.960Lm under a power of 20.425W. The size of the LED lamp can therefore be significantly reduced, thereby achieving the objectives of the present invention.

While the preferred embodiments of the present invention have been illustrated and described in detail, various modifications and alterations can be made by persons skilled in the art. The embodiment of the present invention is therefore described in an illustrative but not restrictive sense.

What is claimed is:

1. A light-emitting diode having a silicon submount, comprising:
a silicon submount comprising a power management integrated circuit formed in an inside of the silicon submount, a P-electrode formed on a bottom side thereof, an N-electrode formed on the bottom side thereof, and a heat dissipation ground portion formed on the bottom side thereof, the power management integrated circuit electrically coupled to the P-electrode and the N-electrode; and
at least one light-emitting diode chip eutecticly bonded to a top side of the silicon submount, the at least one light-emitting diode chip electrically coupled to the P-electrode and the N-electrode,
wherein the silicon submount defines a heat-dissipation channel from the light-emitting diode chip to the heat dissipation ground portion via the inside of the silicon submount.

2. The light-emitting diode of claim 1, wherein the power management integrated circuit is disposed around the heat-dissipation channel.

3. The light-emitting diode of claim 2, wherein the power management integrated circuit is disposed above the P-electrode and the N-electrode.

4. The light-emitting diode of claim 1, wherein the heat-dissipation channel is vertically downward.

5. The light-emitting diode of claim 4, wherein the heat-dissipation channel is coupled to the heat dissipation ground portion.

6. The light-emitting diode of claim 1, wherein the silicon submount further comprises a thermal management integrated circuit.

7. The light-emitting diode of claim 1, wherein the silicon submount further comprises a color-control integrated circuit.

8. A light-emitting diode lamp, comprising:
a heatsink comprising a flat reference surface and a plurality of heatsink platforms protruding from the reference surface;
a circuit board comprising a heatsink bottom surface correspondingly contacting the reference surface of the heatsink and a plurality of grooves defined therein corresponding to the heatsink platforms, the heatsink platforms positioned in the grooves; and
at least one light-emitting diode disposed above the grooves of the circuit board and located on top surfaces of the heatsink platforms of the heatsink, each light-emitting diode comprising a silicon submount and at least one light-emitting diode chip, the silicon submount comprising a power management integrated circuit formed in an inside of the silicon submount, a P-electrode formed on a bottom side thereof, an N-electrode formed on the bottom side thereof, and a heat dissipation ground portion formed on the bottom side thereof, the power management integrated circuit electrically coupled to the P-electrode and the N-electrode, the light-emitting diode chip eutecticly bonded to a top side of the silicon submount, the at least one light-emitting diode chip electrically coupled to the P-electrode and the N-electrode, wherein the silicon submount defines a heat-dissipation channel from the light-emitting diode chip to the heat dissipation ground portion via the inside of the silicon submount.

9. The light-emitting diode lamp of claim 8, wherein the heat-dissipation channel is coupled to the heatsink platform via the heat dissipation ground portion.

10. The light-emitting diode lamp of claim 9, further comprising an intermetallic layer positioned between the heat dissipation ground portion of the silicon submount of the light-emitting diode and the top surface of the heatsink platform of the heatsink.

11. The light-emitting diode lamp of claim 10, wherein the top surface of the heatsink platform of the heatsink plus the intermetallic layer is higher than the circuit board, and wherein a thickness of the intermetallic layer is less than 0.03 mm.

12. The light-emitting diode lamp of claim 10, wherein both the heat dissipation ground portion of the silicon submount and the top surface of the heatsink platform of the heatsink have a gold-tin alloy layer formed thereon, and together form the intermetallic layer.

13. The light-emitting diode lamp of claim 10, wherein an air gap between the heat dissipation ground portion of the silicon submount and the top surface of the heatsink platform of the heatsink is filled by a tin solder.

14. The light-emitting diode lamp of claim 8, wherein the heatsink and the circuit board are welded by using a high-melting-point tin solder; the light-emitting diode and the heatsink as well as the light-emitting diode and the circuit board are welded by using a low-melting-point tin solder.

15. A lamp comprising the light-emitting diode having a silicon submount as claimed in claim 1.
